(19) United States
(12) Patent Application Publication
(10) Pub. No.: US 2012/0241088 A1
(43) Pub. Date: Sep. 27, 2012

(54) CYLINDER CABINET AND SEMICONDUCTOR MANUFACTURING SYSTEM

(75) Inventor: Shinji AKIYOSHI, Mie (JP)

(73) Assignee: KABUSHIKI KAISHA TOSHIBA, Tokyo (JP)

(21) Appl. No.: 13/238,699

(22) Filed: Sep. 21, 2011

(30) Foreign Application Priority Data
Mar. 23, 2011 (JP) 2011-064725

(51) Int. Cl. B05C 11/10; H01L 21/306; F16K 51/00

(52) U.S. Cl. 156/345.26; 137/455; 118/710

(57) ABSTRACT

In a cylinder cabinet of an embodiment, when first pressure in a first gas supply pipe is equal to or less than a predetermined value, a pipe of gas supplied to an external apparatus is switched from the first gas supply pipe to a second gas supply pipe, and when a gas flow rate of gas flowing through the external apparatus is equal to or less than a predetermined value, if a residual gas amount of a first gas container connected to the first gas supply pipe is equal to or more than a predetermined value, the pipe is switched from the second gas supply pipe to the first gas supply pipe.

### CROSS-REFERENCE TO RELATED APPLICATIONS

This application is based upon and claims the benefit of priority from Japanese Patent Application No. 2011-064725, filed on Mar. 23, 2011; the entire contents of which are incorporated herein by reference.

### FIELD

Embodiments described herein relate generally to a cylinder cabinet and a semiconductor manufacturing system.

### BACKGROUND

In a semiconductor manufacturing apparatus, various types of material gases are used according to a semiconductor manufacturing process. The material gases are supplied from a cylinder cabinet disposed adjacent to a semiconductor manufacturing plant to a semiconductor manufacturing apparatus through a gas pipe installed in the semiconductor manufacturing plant.

In a cylinder cabinet of the related art, for example, two gas containers are prepared, and gas is supplied to a semiconductor manufacturing apparatus using any one of the two gas containers. While the gas is being supplied to the semiconductor manufacturing apparatus, residual gas weight, primary pressure, and gas supply pressure (secondary pressure) are measured. Then, if the residual gas weight and the primary pressure in the first gas container reach the lower limit residual weight or primary pressure at which gas supply is stable, a gas supply source is changed from the first gas container to the second gas container to continuous supplying gas.

However, if a gas flow rate in the semiconductor manufacturing apparatus is steeply increased before an amount of a residual gas (corresponds to weight or primary pressure of residual gas) reaches a lower limit value at which gas can be stably supplied, the secondary pressure in the cylinder cabinet is lowered. In this case, the gas supply source is changed from the first gas container to the second gas container. As a consequence, gas exceeding a preset amount remains in the first gas container. Since the first gas container is taken off and a new gas container is installed, the residual gas is returned to a gas maker and is disposed of. Due to such wasteful disposal of the gas, the cost of usage of gas may be increased. In this regard, it is necessary to reduce the wasteful disposal of gas.

### BRIEF DESCRIPTION OF THE DRAWINGS

FIG. 1 is a diagram illustrating the configuration of a cylinder cabinet according to an embodiment;

FIG. 2 is a flowchart illustrating the operation procedure of a cylinder cabinet according to an embodiment; and

FIG. 3 is a flowchart illustrating the replacement procedure of a container.

### DETAILED DESCRIPTION

According to an embodiment, a cylinder cabinet is provided. The cylinder cabinet includes a first gas supply pipe, which is connected to a first gas container of gas supplied to an external apparatus and allows the gas in the first gas container to flow toward the external apparatus, and a second gas supply pipe which is connected to a second gas container of gas supplied to the external apparatus and allows the gas in the second gas container to flow toward the external apparatus. Furthermore, the cylinder cabinet includes automatic valves which are installed on the first gas supply pipe and the second gas supply pipe so as to block or open the flow of the gas, and a flowmeter which measures a gas flow rate of gas flowing from the first gas supply pipe or the second gas supply pipe to the external apparatus. Furthermore, the cylinder cabinet includes a control unit which switches a pipe for supplying the gas by controlling the automatic valves such that the gas is supplied from one of the first and second gas supply pipes to the external apparatus, based on first pressure (pressure of gas in the first gas supply pipe), second pressure (pressure of gas in the second gas supply pipe), and the gas flow rate. When the first pressure is equal to or less than a predetermined value, the control unit switches the pipe from the first gas supply pipe to the second gas supply pipe. Then, when the gas flow rate is equal to or less than a predetermined value, if a residual gas amount of the first gas container is equal to or more than a predetermined amount, the control unit switches the pipe from the second gas supply pipe to the first gas supply pipe.

Hereinafter, a cylinder cabinet and a semiconductor manufacturing system according to an embodiment will be described in detail with reference to the accompanying drawings. In addition, the present invention is not limited to the embodiment.

### Embodiment

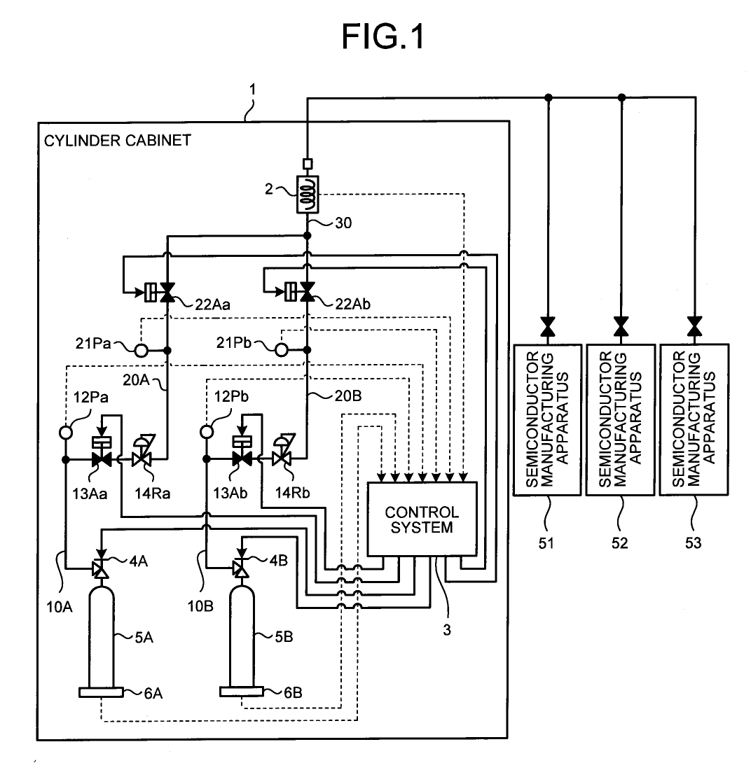

FIG. 1 is a diagram illustrating the configuration of a cylinder cabinet according to the embodiment. A semiconductor manufacturing system includes a cylinder cabinet 1 and semiconductor manufacturing apparatuses 51 to 53. The cylinder cabinet 1 supplies process gas to the semiconductor manufacturing apparatuses 51 to 53 and the like using two gas containers (gas bombes) 5A and 5B. The cylinder cabinet 1 of the present embodiment switches a gas supply source of the process gas, which is supplied to the semiconductor manufacturing apparatuses 51 to 53, to the gas container 5A or the gas container 5B.

The cylinder cabinet 1 includes a control system 3 which controls each element of the cylinder cabinet 1. Furthermore, the cylinder cabinet 1 includes a flowmeter 2 which measures a gas flow rate of the process gas supplied to the semiconductor manufacturing apparatuses 51 to 53.

In the present embodiment, the control system 3 switches the gas supply source of the process gas, which is supplied to the semiconductor manufacturing apparatuses 51 to 53, based on primary pressure of the process gas supplied to the semiconductor manufacturing apparatuses 51 to 53, a gas flow rate, and residual gas amounts in the gas containers 5A and 5B.

The cylinder cabinet 1 is provided therein with the gas container 5A and the gas container 5B. The cylinder cabinet 1 includes process gas supply pipes 10A and 20A through which process gas is discharged from the gas container 5A to the semiconductor manufacturing apparatuses 51 to 53. Furthermore, the cylinder cabinet 1 includes process gas supply pipes 10B and 20B through which process gas is discharged from the gas container 5B to the semiconductor manufacturing apparatuses 51 to 53.

In the cylinder cabinet 1, the gas container 5A, the process gas supply pipe 10A, and the process gas supply pipe 20A are sequentially connected in this order from the upstream side of process gas. Thus, the process gas supply pipe 10A is a primary pipe on the gas container 5A side and the process gas supply pipe 20A is a secondary pipe on the gas container 5A side.

In the same manner, in the cylinder cabinet 1, the gas container 5B, the process gas supply pipe 10B, and the process gas supply pipe 20B are sequentially connected in this order from the upstream side of process gas. Thus, the process gas supply pipe 10B is a primary pipe on the gas container 5B side and the process gas supply pipe 20B is a secondary pipe on the gas container 5B side.

The process gas supply pipe 20A and the process gas supply pipe 20B are connected to a process gas supply pipe (a gas supply path) 30 at an outlet through which process gas is discharged to the semiconductor manufacturing apparatuses 51 to 53. Thus, the process gas supply pipe 30 is a secondary pipe of the gas containers 5A and 5B. With such a configuration, process gas discharged from the process gas supply pipes 10A and 20A or the process gas supply pipes 10B and 20B is supplied to the semiconductor manufacturing apparatuses 51 to 53 via the process gas supply pipe 30.

The process gas supply pipe 10A is provided with a pressure gauge 12Pa, an automatic valve 13Aa, and a pressure regulating valve (a pressure reducing valve) 14Ra. Furthermore, the process gas supply pipe 20A is provided with a pressure gauge 21Pa and an automatic valve 22Aa. Results of pressure in pipes measured by the pressure gauges 12Pa and 21Pa are sent to the control system 3 as pressure measurement results on the side of the gas container 5A. The pressure measurement result of the pressure gauges 12Pa is a pressure measurement result at the primary pipe, and the pressure measurement result of the pressure gauges 21Pa is a pressure measurement result at the secondary pipe.

In the same manner, the process gas supply pipe 10B is provided with a pressure gauge 12Pb, an automatic valve 13Ab, and a pressure regulating valve (a pressure reducing valve) 14Rb. Furthermore, the process gas supply pipe 20B is provided with a pressure gauge 21Pb and an automatic valve 22Ab. Results of pressure in pipes measured by the pressure gauges 12Pb and 21Pb are sent to the control system 3 as pressure measurement results on of the side of the gas container 5B. The pressure measurement result of the pressure gauges 12Pb is a pressure measurement result at the primary pipe, and the pressure measurement result of the pressure gauges 21Pb is a pressure measurement result at the secondary pipe.

Furthermore, the process gas supply pipe 30 is provided with a flowmeter 2 which is one of the characteristics of the present embodiment. The flowmeter 2 is an apparatus for measuring the flow rate of process gas flowing through the process gas supply pipe 30, and measures the flow rate of the process gas supplied from the gas container 5A or the gas container 5B to the semiconductor manufacturing apparatuses 51 to 53.

Furthermore, a weighing device 6A is installed at the place where the gas container 5A is installed, and a weighing device 6B is installed at the place where the gas container 5B is installed. The weighing devices 6A and 6B measure residual gas weight in the gas containers 5A and 5B, respectively. Measurement results of weight measured by the weighing devices 6A and 6B are sent to the control system 3 as a residual gas weight measurement result on the side of the gas container 5A and a residual gas weight measurement result on the side of the gas container 5B. Furthermore, the gas containers 5A and 5B are provided with container valves 4A and 4B, respectively. When gas is discharged, the container valves 4A and 4B are opened.

In the present invention, for example, it is determined whether to replace the gas container 5A with a new gas container 5A based on the measurement result of the residual gas weight measured by the weighing device 6A. In the same manner, it is determined whether to replace the gas container 5B with a new gas container 5B based on the measurement result of the residual gas weight measured by the weighing device 6B.

The control system 3, for example, is a computer for controlling a gas supply source (the gas container 5A or the gas container 5B) of the process gas, which is supplied to the semiconductor manufacturing apparatuses 51 to 53, by controlling the automatic valves 13Aa, 13Ab, 22Aa and 22Ab and the pressure regulating valves 14Ra and 14Rb. In addition, the automatic valves 13Aa, 13Ab, 22Aa and 22Ab block or open the flow of gas, and each automatic valve is controlled to switch the flow of gas.

For example, when process gas to the semiconductor manufacturing apparatuses 51 to 53 is supplied using the gas container 5A, valves (the container valve 4B, the automatic valves 13Ab and 22Ab and the like) installed on the side of the gas container 5B are closed. Then, the container valve 4A and the automatic valves 13Aa and 22Aa are opened. In this way, the process gas is supplied to the semiconductor manufacturing apparatuses 51 to 53 via the process gas supply pipes 10A, 20A and 30.

In the same manner, when process gas to the semiconductor manufacturing apparatuses 51 to 53 is supplied using the gas container 5B, valves (the container valve 4A, the automatic valves 13Aa and 22Aa and the like) installed on the side of the gas container 5A are closed. Then, the container valve 4B and the automatic valves 13Ab and 22Ab are opened. In this way, the process gas is supplied to the semiconductor manufacturing apparatuses 51 to 53 via the process gas supply pipes 10B, 20B and 30.

When process gas to the semiconductor manufacturing apparatuses 51 to 53 is supplied using the gas containers 5A and 5B, the flowmeter 2 measures the gas flow rate of the process gas supplied to the semiconductor manufacturing apparatuses 51 to 53. The measurement result is sent to the control system 3 from the flowmeter 2.

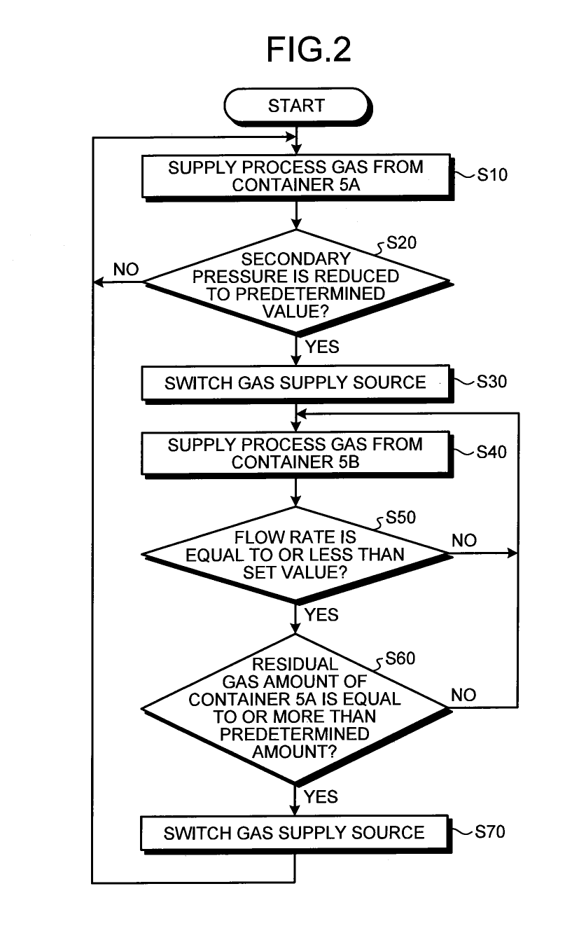

Next, the operation procedure of the cylinder cabinet 1 according to the embodiment will be described. FIG. 2 is a flowchart illustrating the operation procedure of the cylinder cabinet according to the embodiment.

In the cylinder cabinet 1, while process gas is being supplied to the semiconductor manufacturing apparatuses 51 to 53 from the gas containers 5A and 5B, the pressure gauges 12Pa, 21Pa, 12Pb and 21Pb measure pressure. Furthermore, the weighing devices 6A and 6B measure residual gas weight in the gas container 5A and residual gas weight in the gas container 5B, respectively. Furthermore, the flowmeter 2 measures the flow rate of the process gas. Then, the pressure measurement results, the residual gas weight measurement results, and the flow rate measurement result are sent to the control system 3.

When process gas to the semiconductor manufacturing apparatuses 51 to 53 is supplied using the gas container 5A, the control system 3 closes the valves (the automatic valves 13Ab and 22Ab and the like) installed on the side of the gas container 5B, and opens the container valve 4A and the automatic valves 13Aa and 22Aa. In this way, the process gas is supplied to the semiconductor manufacturing apparatuses 51 to 53 from the gas container 5A (step S10). In addition, the container valve 4A and the automatic valves 13Aa may be opened in advance.

The control system 3 determines whether secondary pressure has been reduced to a predetermined value based on the pressure measurement result (the measurement result by the pressure gauge 21Pa) at the secondary pipe on the side of the gas container 5A (step S20). When the secondary pressure on the side of the gas container 5A is equal to or more than the predetermined value (No in step S20), the control system 3 continues the supply of the process gas from the gas container 5A (step S10).

Meanwhile, if the secondary pressure on the side of the gas container 5A is smaller than the predetermined value (Yes in step S20), the control system 3 switches a gas supply source of the process gas from the gas container 5A to the gas container 5B (step S30). In detail, the control system 3 closes the valves (the container valve 4A, the automatic valves 13Aa and 22Aa and the like) installed on the side of the gas container 5A, and opens the container valve 4B and the automatic valves 13Ab and 22Ab. In this way, the process gas is supplied from the gas container 5B to the semiconductor manufacturing apparatuses 51 to 53 (step S40). In addition, the container valve 4B and the automatic valve 13Ab may be opened in advance.

The secondary pressure on the side of the gas container 5A is smaller than the predetermined value when the residual gas amount of the gas container 5A becomes small and the gas flow rate of the process gas supplied to the semiconductor manufacturing apparatuses 51 to 53 is steeply increased. In the present embodiment, when the gas flow rate of the process gas supplied to the semiconductor manufacturing apparatuses 51 to 53 is steeply increased, a gas supply source is once switched from the gas container 5A to the gas container 5B. Then, at the time at which the gas flow rate is stable, the gas supply source is returned to the gas container 5A from the gas container 5B. Furthermore, when the residual gas amount of the gas container 5A is smaller than the predetermined amount, the gas supply source is switched from the gas container 5A to the gas container 5B. Then, the supply of the process gas by the gas container 5B is continued, and the gas container 5A is replaced with a new gas container 5A.

While the process gas is being supplied to the semiconductor manufacturing apparatuses 51 to 53 from the gas container 5B, the control system 3 determines whether the flow rate of the process gas supplied to the semiconductor manufacturing apparatuses 51 to 53 is equal to or less than a set value based on the flow rate measurement result sent from the flowmeter 2 (step S50).

When the flow rate of the process gas is larger than the set value (No in step S50), the control system 3 continues the supply of the process gas from the gas container 5B (step S40). Meanwhile, if the flow rate of the process gas is equal to or less than the set value (Yes in step S50), the control system 3 determines whether the residual gas amount of the gas container 5A is equal to or more than a predetermined amount (step S60). At this time, the control system 3 may determine the residual gas amount of the gas container 5A based on the residual gas weight measurement result sent from the weighing device 6A, or may determine the residual gas amount of the gas container 5A based on the pressure measurement result (the pressure measurement result at the primary pipe on the side of the container 5A) (the primary pressure), which is sent from the automatic valve 13Aa. For example, if the residual gas weight measurement result or the pressure measurement result is smaller than a lower limit value at which gas can be stably supplied, it is determined that the gas in the gas container 5A is not used for supply.

When the residual gas amount of the gas container 5A is smaller than the predetermined amount (No in step S60), the control system 3 continues the supply of the process gas from the gas container 5B (step S40). While the process gas is being supplied from the gas container 5B, the gas container 5A is replaced with a new gas container 5A.

Meanwhile, when the residual gas amount of the gas container 5A is equal to or more than the predetermined amount (Yes in step S60), the control system 3 switches a gas supply source of the process gas from the gas container 5B to the gas container 5A (step S70). In detail, the control system 3 closes the valves (the container valve 4B, the automatic valves 13Ab and 22Ab and the like) installed on the side of the gas container 5B, and opens the container valve 4A and the automatic valves 13Aa and 22Aa. In this way, the process gas is supplied to the semiconductor manufacturing apparatuses 51 to 53 from the gas container 5A (step S10).

In the cylinder cabinet 1, the processes of steps S10, S20, S30, S40, S50, S60 and S70 are repeated until the gas container 5A is replaced with the new gas container 5A. Since the residual gas amount of the gas container 5A is smaller than the predetermined amount, when the gas container 5A has been replaced with the new gas container 5A, the supply of the process gas from the gas container 5B is continued. Then, the cylinder cabinet 1 performs the same processes as those in steps S10, S20, S30, S40, S50, S60 and S70 in order to supply process gas using the gas container 5B.

In detail, the control system 3 determines whether the secondary pressure has been reduced to a predetermined value based on the pressure measurement result (the measurement result of the pressure gauge 21Pb) at the secondary pipe on the side of the gas container 5B. When the secondary pressure on the side of the gas container 5B is equal to or more than the predetermined value, the control system 3 continues the supply of the process gas from the gas container 5B.

Meanwhile, if the secondary pressure on the side of the gas container 5B is smaller than the predetermined value, the control system 3 switches a gas supply source of the process gas from the gas container 5B to the gas container 5A. In this way, the process gas is supplied to the semiconductor manufacturing apparatuses 51 to 53 from the gas container 5A.

While the process gas is being supplied to the semiconductor manufacturing apparatuses 51 to 53 from the gas container 5A, the control system 3 determines whether the flow rate of the process gas supplied to the semiconductor manufacturing apparatuses 51 to 53 is smaller than a set value based on the flow rate measurement result sent from the flowmeter 2.

When the flow rate of the process gas is larger than the set value, the control system 3 continues the supply of the process gas from the gas container 5A. Meanwhile, if the flow rate of the process gas is equal to or less than the set value, the control system 3 determines whether the residual gas amount of the gas container 5B is equal to or more than a predetermined amount.

When the residual gas amount of the gas container 5B is smaller than the predetermined amount, the control system 3 continues the supply of the process gas from the gas container 5A. While the process gas is being supplied from the gas container 5A, the gas container 5B is replaced with a new gas container 5B.

Meanwhile, when the residual gas amount of the gas container 5B is equal to or more than the predetermined amount, the control system 3 switches a gas supply source of the process gas from the gas container 5A to the gas container 5B. In this way, the process gas is supplied to the semiconductor manufacturing apparatuses 51 to 53 from the gas container 5B.

In the cylinder cabinet 1, the supply of the process gas from the gas container 5A, the switching of the gas supply source from the gas container 5A to the gas container 5B, the switching of the gas supply source from the gas container 5B to the gas container 5A, the supply of the process gas from the gas container 5B, the replacement of the gas container 5A, the replacement of the gas container 5B and the like are sequentially repeated.

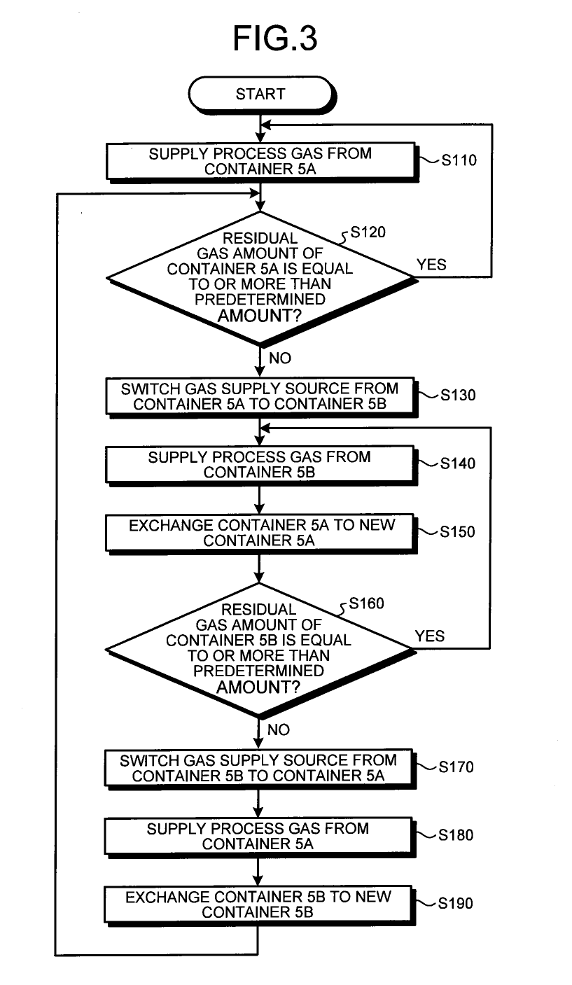

FIG. 3 is a flowchart illustrating the replacement procedure of the container. The process gas is supplied from the gas container 5A to the semiconductor manufacturing apparatuses 51 to 53 (step S110). At this time, when the secondary pressure on the side of the gas container 5A has been reduced to a predetermined value, the gas container 5A is switched to the gas container 5B. Then, if the flow rate of the process gas is equal to or less than a set value, the gas container 5B is switched to the gas container 5A.

The control system 3 determines whether the residual gas amount of the gas container 5A is equal to or more than a predetermined amount (step S120). When the residual gas amount of the gas container 5A is equal to or more than the predetermined amount (Yes in step S120), the supply of the process gas from the gas container 5A is continued. Meanwhile, when the residual gas amount of the gas container 5A is smaller than the predetermined amount (No in step S120), the control system 3 switches a gas supply source from the gas container 5A to the gas container 5B (step S130). In this way, the process gas is supplied to the semiconductor manufacturing apparatuses 51 to 53 from the gas container 5B (step S140).

While the process gas is being supplied from the gas container 5B, the gas container 5A is replaced with a new gas container 5A (step S150). At this time, when the secondary pressure on the side of the gas container 5B has been reduced to a predetermined value, the gas container 5B is switched to the gas container 5A. Then, if the flow rate of the process gas is equal to or less than a set value, the gas container 5A is switched to the gas container 5B.

The control system 3 determines whether the residual gas amount of the gas container 5B is equal to or more than a predetermined amount (step S160). When the residual gas amount of the gas container 5B is equal to or more than the predetermined amount (Yes in step S160), the supply of the process gas from the gas container 5B is continued. Meanwhile, when the residual gas amount of the gas container 5B is smaller than the predetermined amount (No in step S160), the control system 3 switches a gas supply source from the gas container 5B to the gas container 5A (step S170). In this way, the process gas is supplied from the gas container 5A to the semiconductor manufacturing apparatuses 51 to 53 (step S180).

While the process gas is being supplied from the gas container 5A, the gas container 5B is replaced with a new gas container 5B (step S190). Then, in the cylinder cabinet 1, the processes of steps S120 to S190 are repeated.

In the semiconductor manufacturing apparatuses 51 to 53, semiconductor apparatuses are manufactured using the process gas from the cylinder cabinet 1. In addition, the cylinder cabinet 1 may supply the process gas to apparatuses other than the semiconductor manufacturing apparatuses 51 to 53.

The semiconductor manufacturing apparatuses 51 to 53, for example, include a film formation apparatus, an etching apparatus and the like. When a semiconductor apparatus (a semiconductor integrated circuit) is manufactured, a mask such as a photomask is produced and exposure is performed on a wafer coated with resist using the mask. Then, the wafer is developed to form a resist pattern on the wafer. Then, the lower layer side of the wafer is etched using the resist pattern as a mask. In this way, a real pattern corresponding to the resist pattern is formed on the wafer. When the semiconductor apparatus is manufactured, a film formation process, an exposure process, a development process, an etching process and the like are repeated for each layer.

In addition, the number of gas containers installed in the cylinder cabinet 1 may be three or more. Even in such a case, process gas supply pipes, pressure gauges, automatic valves, pressure regulating valves, weighing devices and the like are installed for each of the gas containers.

As described above, since the cylinder cabinet 1 includes the flowmeter 2 in the vicinity of a gas supply port to the semiconductor manufacturing apparatuses 51 to 53, it is possible to accurately measure the supply amount of the process gas supplied to the semiconductor manufacturing apparatuses 51 to 53.

Furthermore, in the cylinder cabinet 1, when secondary pressure of process gas to be supplied is smaller than a predetermined value, a gas supply source is switched from one container (for example, the gas container 5A) to the other container (for example, the gas container 5B). Even in such a case, when a gas flow rate measured by the flowmeter 2 is equal to or less than a predetermined value and a predetermined amount or more of residual gas remains in one container, the process gas is supplied again from one container to the semiconductor manufacturing apparatuses 51 to 53. Thus, it is possible to use residual gas in a gas container as process gas.

According to the embodiment as described above, a gas supply source is switched based on the gas flow rate measured by the flowmeter 2, so that it is possible to reuse a gas container in which secondary pressure of supplied process gas is smaller than a predetermined value. Thus, it is possible to continuously use gas in the gas containers 5A and 5B up to set residual weight or residual pressure. Consequently, it is possible to reduce the wasteful disposal of gas and reduce the cost used in gas.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cylinder cabinet comprising:
a first gas supply pipe that is connected to a first gas container for gas to be supplied to an external apparatus so as to allow the gas in the first gas container to flow toward the external apparatus;
a second gas supply pipe that is connected to a second gas container for gas to be supplied to the external apparatus so as to allow the gas in the second gas container to flow toward the external apparatus;
automatic valves that are installed on the first and second gas supply pipes, respectively so as to block or open flow of the gas;
a flowmeter that measures a gas flow rate of gas flowing from the first or second gas supply pipe to the external apparatus; and
a control unit that switches a pipe for supplying the gas by controlling the automatic valves such that the gas is supplied from one of the first and second gas supply pipes to the external apparatus, based on first pressure, second pressure, and the gas flow rate, the first pressure indicating pressure of gas in the first gas supply pipe and the second pressure indicating pressure of gas in the second gas supply pipe,
wherein, when the first pressure is equal to or less than a predetermined value, the control unit switches the pipe from the first gas supply pipe to the second gas supply pipe, and when the gas flow rate is equal to or less than a predetermined value, if a residual gas amount of the first gas container is equal to or more than a predetermined amount, the control unit switches the pipe from the second gas supply pipe to the first gas supply pipe.

2. The cylinder cabinet according to claim 1,
wherein, when the first pressure is equal to or less than a predetermined value, the control unit switches the pipe from the first gas supply pipe to the second gas supply pipe, and when the gas flow rate is equal to or less than a predetermined value, if the residual gas amount of the first gas container is smaller than a predetermined amount, the control unit controls the automatic valves such that the gas is continuously supplied from the second gas supply pipe to the external apparatus.

3. The cylinder cabinet according to claim 1,
further comprising:
a first weight measurement unit that measures residual gas weight of the first gas container,
wherein the residual gas amount of the first gas container is measured by the first weight measurement unit.

4. The cylinder cabinet according to claim 1,
further comprising:
a first pressure measurement unit that measures primary pressure of gas discharged from the first gas container,
wherein the residual gas amount of the first gas container is measured by the first pressure measurement unit.

5. The cylinder cabinet according to claim 1,
wherein, when the second pressure is equal to or less than a predetermined value, the control unit switches the pipe from the second gas supply pipe to the first gas supply pipe, and after that when the gas flow rate is equal to or less than a predetermined value, if a residual gas amount of the second gas container is equal to or more than a predetermined amount, the control unit switches the pipe from the first gas supply pipe to the second gas supply pipe.

6. The cylinder cabinet according to claim 5,
wherein, when the second pressure is equal to or less than a predetermined value, the control unit switches the pipe from the second gas supply pipe to the first gas supply pipe, and after that when the gas flow rate is equal to or less than a predetermined value, if the residual gas amount of the second gas container is smaller than a predetermined amount, the control unit controls the automatic valves such that the gas is continuously supplied from the first gas supply pipe to the external apparatus.

7. The cylinder cabinet according to claim 5,
further comprising:
a second weight measurement unit that measures residual gas weight of the second gas container,
wherein the residual gas amount of the second gas container is measured by the second weight measurement unit.

8. The cylinder cabinet according to claim 5,
further comprising:
a second pressure measurement unit that measures primary pressure of gas discharged from the second gas container,
wherein the residual gas amount of the second gas container is measured by the second pressure measurement unit.

9. The cylinder cabinet according to claim 1,
further comprising:
a third pressure measurement unit that measures the first pressure,
wherein the control unit controls the automatic valves based on the first pressure measured by the third pressure measurement unit.

10. The cylinder cabinet according to claim 1,
further comprising:
a fourth pressure measurement unit that measures the second pressure,
wherein the control unit controls the automatic valves based on the second pressure measured by the fourth pressure measurement unit.

11. A semiconductor manufacturing system comprising:
a semiconductor manufacturing apparatus which manufactures a semiconductor using gas;
a first gas supply pipe that is connected to a first gas container for gas to be supplied to the semiconductor manufacturing apparatus so as to allow the gas in the first gas container to flow toward the semiconductor manufacturing apparatus;
a second gas supply pipe that is connected to a second gas container for gas to be supplied to the semiconductor manufacturing apparatus so as to allow the gas in the second gas container to flow toward the semiconductor manufacturing apparatus;
automatic valves that are installed on the first and second gas supply pipes, respectively so as to block or open flow of the gas;
a flowmeter that measures a gas flow rate of gas flowing from the first or second gas supply pipe to the semiconductor manufacturing apparatus; and
a control unit that switches a pipe for supplying the gas by controlling the automatic valves such that the gas is supplied from one of the first and second gas supply pipes to the semiconductor manufacturing apparatus, based on first pressure, second pressure, and the gas flow rate, the first pressure indicating pressure of gas in the first gas supply pipe and the second pressure indicating pressure of gas in the second gas supply pipe,
wherein, when the first pressure is equal to or less than a predetermined value, the control unit switches the pipe from the first gas supply pipe to the second gas supply pipe, and when the gas flow rate is equal to or less than a predetermined value, if a residual gas amount of the first gas container is equal to or more than a predetermined amount, the control unit switches the pipe from the second gas supply pipe to the first gas supply pipe.

12. The semiconductor manufacturing system according to claim 11,
wherein, when the first pressure is equal to or less than a predetermined value, the control unit switches the pipe from the first gas supply pipe to the second gas supply pipe, and when the gas flow rate is equal to or less than a predetermined value, if the residual gas amount of the first gas container is smaller than a predetermined amount, the control unit controls the automatic valves such that the gas is continuously supplied from the second gas supply pipe to the semiconductor manufacturing apparatus.

13. The semiconductor manufacturing system according to claim 11,
further comprising:
a first weight measurement unit that measures residual gas weight of the first gas container,
wherein the residual gas amount of the first gas container is measured by the first weight measurement unit.

14. The semiconductor manufacturing system according to claim 11, further comprising:
a first pressure measurement unit that measures primary pressure of gas discharged from the first gas container,
wherein the residual gas amount of the first gas container is measured by the first pressure measurement unit.

15. The semiconductor manufacturing system according to claim 11,
wherein, when the second pressure is equal to or less than a predetermined value, the control unit switches the pipe from the second gas supply pipe to the first gas supply pipe, and after that when the gas flow rate is equal to or less than a predetermined value, if a residual gas amount of the second gas container is equal to or more than a predetermined amount, the control unit switches the pipe from the first gas supply pipe to the second gas supply pipe.

16. The semiconductor manufacturing system according to claim 15,
wherein, when the second pressure is equal to or less than a predetermined value, the control unit switches the pipe from the second gas supply pipe to the first gas supply pipe, and after that when the gas flow rate is equal to or less than a predetermined value, if the residual gas amount of the second gas container is smaller than a predetermined amount, the control unit controls the automatic valves such that the gas is continuously supplied from the first gas supply pipe to the semiconductor manufacturing apparatus.

17. The semiconductor manufacturing system according to claim 15, further comprising a second weight measurement unit which measures residual gas weight of the second gas container,
wherein the residual gas amount of the second gas container is measured by the second weight measurement unit.

18. The semiconductor manufacturing system according to claim 15, further comprising a second pressure measurement unit that measures primary pressure of gas discharged from the second gas container,
wherein the residual gas amount of the second gas container is measured by the second pressure measurement unit.

19. The semiconductor manufacturing system according to claim 11, further comprising a third pressure measurement unit that measures the first pressure,
wherein the control unit controls the automatic valves based on the first pressure measured by the third pressure measurement unit.

20. The semiconductor manufacturing system according to claim 11, further comprising a fourth pressure measurement unit that measures the second pressure,
wherein the control unit controls the automatic valves based on the second pressure measured by the fourth pressure measurement unit.
